(19) United States
(12) Patent Application Publication
(10) Pub. No.: US 2003/0183405 A1
(43) Pub. Date: Oct. 2, 2003

(54) Electrical circuit and substrate therefor

(76) Inventors: Albert-Andreas Hoebel, Reutlingen (DE); Frank Heider, Reutlingen (DE); Bernd Rautzenberg, Sibbesse (DE); Thomas Raica, Hechingen (DE); Andreas Haugeneder, Reutlingen (DE)

Correspondence Address: KENYON & KENYON, ONE BROADWAY, NEW YORK, NY, 10004, US

(21) Appl. No.: 10/221,009

(22) PCT Filed: Mar. 1, 2001
(86) PCT No.: PCT/DE01/00766

(30) Foreign Application Priority Data
Mar. 7, 2000 (DE) 100 10 979.9

(51) Int. Cl. H02G 3/08; H05K 5/00

(52) U.S. Cl. 174/52.1

(57) ABSTRACT

An electrical circuit on a substrate (10), having at least one component (30, 40) attached to a conductor layer (20, 21, 22, 23, 24, 25), is proposed; the component is surrounded by depressions (50, 51, 60) in the conductor layer. In addition, a substrate having at least one conductor layer for attaching at least one electrical component is proposed, the conductor layer having depressions to provide a flow barrier for a connecting material which is used for attaching the component; the depressions surround an area for attaching the component, and are positioned at a distance from each other such that the component has room between them, without the depressions having to be covered by the component.

### BACKGROUND INFORMATION

The present invention is directed to an electrical circuit on a substrate and to a substrate, according to the definition of the species in the independent claims. Attaching components for example to a printed circuit board by soldering is known. The components must be attached at certain locations in order to enable bonding and electrical testing and to prevent short circuits, and to ensure dense packing of the circuit. To limit the area in which the solder can spread out during assembly, it is known to apply masking lacquer to the substrate or conductor, or to attach demarcating materials which rise above the substrate surface (soldering masks) to the substrate before soldering.

### ADVANTAGES OF THE INVENTION

The circuit and the substrate according to the present invention, having the characterizing features of the independent claims, have the advantage over the related art that a solder masking structure may be implemented without additional process steps for well-defined placement of components, that is, to prevent them from “floating away” or to reduce tipping of the component during assembly. The depressions may be produced together with the structuring of the conductors in one step. In addition, the depressions leave the properties of the substrate unaffected, in contrast to the use of a lost soldering mask. The depressions designed as holes or trenches also contribute to stabilizing the mechanical connection for example between the metallic conductor layer and the ceramic substrate, which are two materials of widely different coefficients of expansion.

The measures cited in the dependent claims and in the description make advantageous refinements of and improvements to the devices shown in the independent claims possible.

### DRAWING

Exemplary embodiments of the present invention are depicted in the drawing and in the following description.

FIG. 1a shows a circuit having conductor layers which have holes. FIG. 1b shows a circuit having a conductor layer which has elongated depressions (trenches).

FIG. 2 shows a side view in cross section.

### DETAILED DESCRIPTION OF THE EXEMPLARY EMBODIMENTS

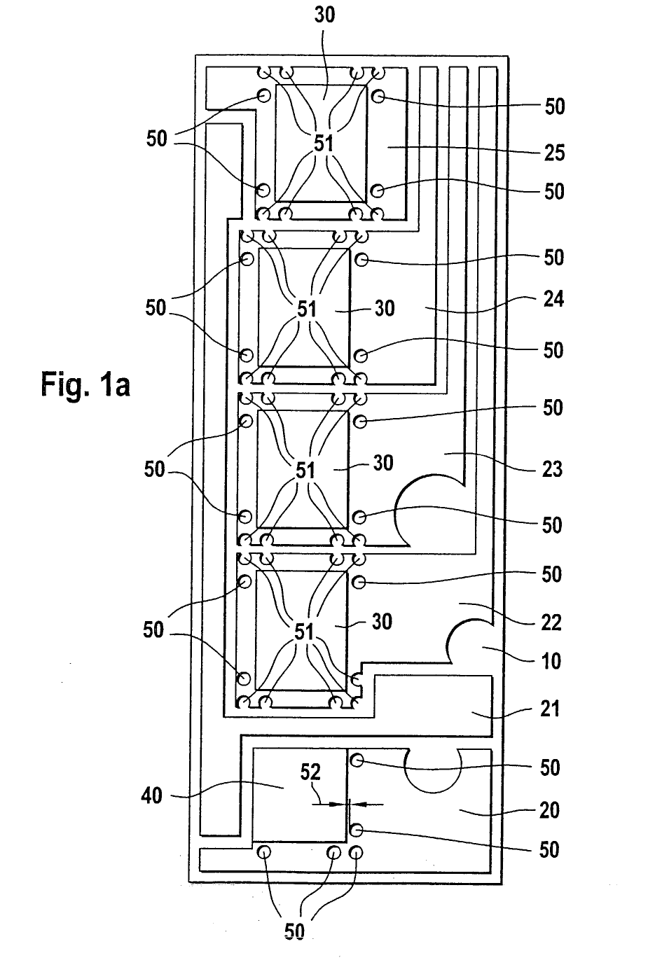

FIG. 1a shows a circuit board 10 having conductor layers 20, 21, 22, 23, 24 and 25 positioned on the surface of the substrate. Components 30 and/or 40, for example power modules, transistor chips, or diode chips, are placed on the conductor layers. These components have their underside in electrical contact with the particular conductor layer via a soldered connection. The components are surrounded at their corners by holes (“dimples”) 50 and 51 in the particular conductor layer. Reference symbol 51 marks what are known as marginal holes, i.e. holes which do not have a complete circular form since the distance from their center to the edge of the conductor layer is smaller than their radius. Distance 52 between the edge of a component and the edges of the holes is 200 micrometers here. FIG. 1b shows a circuit board 10 having a conductor layer 26 analogous to FIG. 1a. Adjacent to component 30 on one side are two trenches 60 in the conductor layer. The distance between the trenches and component 30 corresponds approximately to distance 52 illustrated in FIG. 1a. The two trenches 60 are separated from each other by a connecting tie 70.

The function of the holes or trenches in a soldered assembly is to define the position of components on the circuit board (more generally on the substrate). If solder is applied to the layer onto which a component is to be attached, the holes or trenches constitute a barrier (a poorly wettable area) past which the component cannot float. This is due to the restoring forces which arise for the solder and the component “floating” on it as soon as the component reaches the boundary by “floating away” during assembly. This ensures a defined placement of the component. These restoring forces have their origin in the lower wettability of the circuit board at the floor of the hole or trench in comparison to the conductor layer, and to the surface tension of the solder. A component which “floats to” the demarcating structure continues to be wetted on its underside by the solder, while the solder on the circuit board cannot surmount the hole or trench structure which acts as a solder barrier. The conductor layers between the holes or trenches conduct the electrical current for the solder contacting of the component, and at the same time dissipate heat from the component. Depending on the requisite electrical conductivity and heat conductivity of the conductor layer, trenches or holes of different lengths and numbers may be used to support the placement of the components. The distance from the edge of the component to the edge of the hole or trench should not be less than a certain minimum, for example 200 micrometers, within the framework of the existing assembly tolerance, which is defined in part by the automatic component inserters which place the components on the circuit board, in order to only partially fill the demarcation structure (holes or trenches) after remelting when a reflow method is used. The greater the distance chosen, the worse the positioning accuracy achieved by the demarcation structure.

Alternatively, the circuit board may be a DBC (direct bonded copper) substrate, or may be made of other substrate materials, for example IMS (insulated metal substrate). Holes 50, 51 may also be located along the side edges, not only at the corners, although the position definition is already ensured by the holes at the corners, and filling out the side areas with holes merely increases the restoring force. Trenches 60 may also be provided on all or at least several sides of the component; alternatively, connecting ties 70 may also be partially eliminated. The demarcation of the metal layer under the component from the rest of the conductor layer is limited by the maximum current to be carried, which must flow through the areas between the holes or trenches. Conversely, a plurality of connecting ties 70 per side of the component may also be chosen, so that ultimately transitional forms are implementable, even strings of holes 50, 51 on every side.

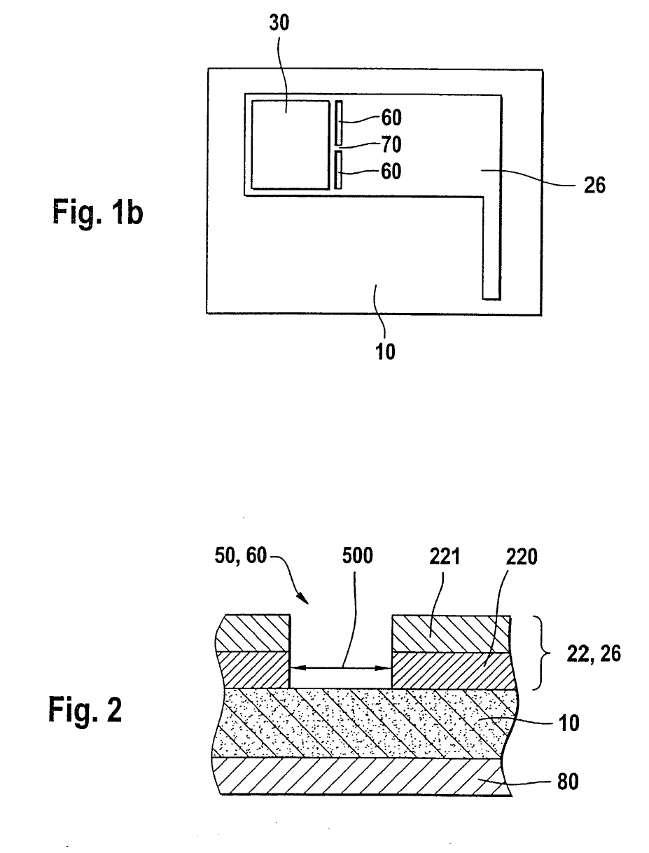

FIG. 2 depicts a cross sectional side view of part of a DBC substrate 10 according to FIG. 1. The back side of the substrate has a copper layer 80. On the front side, conductor layer 22 (FIG. 1a) or 26 (FIG. 1b) is portrayed in the vicinity of a hole 50 or a trench 60. Hole 50 (trench 60) has a diameter 500 (a dimension perpendicular to the edge of the component) greater than 400 micrometers, preferably 800 micrometers (determined by the etching process). The conductor layer has a first metal layer 220 of copper, which is applied directly to the substrate; the metal plating of the back side is made of the same metal. Second layer 221, applied to the first metal layer, is a lamination of gold and nickel, the nickel partial layer being applied to the copper and the gold partial layer to the nickel partial layer. The metal plating of the back has a layer thickness of typically 300 micrometers, electrical insulation layer 10, made for example of ceramic material, has a thickness of 600 micrometers, first metal layer 220 (copper layer) a thickness of around 300 micrometers, the nickel partial layer a thickness of around 20 to 70 micrometers, and the gold partial layer a thickness of around 0.02 to 0.1 micrometers.

Holes 50, 51 or trenches 60 are structured on the substrate together with the conductor layers. The poorer wettability of the solder in the demarcation structure than on the conductor layers comes from the fact that the floor of the demarcation structure is of non-wettable substrate material (for example ceramic), so that while the solder is still able to wet the walls of the demarcation structure, it does not completely fill the structure because of the floor between them. In an alternative embodiment, parts of the side walls of the holes or trenches may also be made of substrate or circuit board material. However, then the demarcation structure must be introduced in a separate work step by removing material, this removal of material also involving substrate 10 at least in part. In addition, the conductor walls of the demarcation structure may also be selectively oxidized, causing them to wet poorly. In such an embodiment, in which also the walls or at least also part of the wall surfaces of the demarcation structure are not wetted, because of the resulting increase in the barrier effect, a hole diameter smaller than 400 micrometers may also be chosen.

What is claimed is:

1. An electrical circuit on a substrate (10), having at least one component (30, 40) attached to a conductor layer (20, 21, 22, 23, 24, 25),
wherein the component is surrounded by depressions (50, 51, 60) in the conductor layer.

2. The electrical circuit as recited in claim 1,
wherein the component is soldered or bonded onto the conductor layer.

3. The electrical circuit as recited in one of the preceding claims,
wherein the depressions are designed in particular in the form of round holes or in the form of trenches.

4. The electrical circuit as recited in one of the preceding claims,
wherein the floor of the depressions is formed by the substrate.

5. The electrical circuit as recited in claim 4,
wherein the side walls of the depressions are formed partially by the substrate.

6. The electrical circuit as recited in one of the preceding claims,
wherein the substrate is a circuit board or a ceramic board.

7. The electrical circuit as recited in one of the preceding claims,
wherein the conductor layer includes a copper layer, a nickel layer, and a gold layer, the copper layer being applied to the substrate, the nickel layer to the copper layer, and the gold layer to the copper layer.

8. A substrate having at least one conductor layer for attaching at least one electrical component,
wherein the conductor layer has depressions to provide a flow barrier for a bonding material which is used to attach the component, the depressions surrounding an area for attaching the component and being positioned at a distance from each other in such a way that the component has room between them, without the depressions having to be covered by the component.

9. The substrate as recited in claim 8,
wherein the depressions are designed in particular in the form of round holes or in the form of trenches.

10. The substrate as recited in claim 8 or 9,
wherein the floor of the depressions is formed by the substrate.

11. The substrate as recited in claim 8, 9 or 10,
wherein the side walls of the depressions are formed partially by the substrate.

12. The substrate as recited in one of claims 8 through 11,
wherein the conductor layer includes a copper layer, a nickel layer, and a gold layer, the copper layer being applied to the substrate, the nickel layer to the copper layer, and the gold layer to the copper layer.
